(19) United States
(12) Patent Application Publication
(10) Pub. No.: US 2026/0267381 A1
(43) Pub. Date: Sep. 10, 2026

(54) COMPUTER CHASSIS WITH HEAT DISSIPATION AND TRANSPARENCY

(71) Applicant: AMERICAN FUTURE TECHNOLOGY, City of Industry, CA (US)

(72) Inventor: You-Chi LIU, City of Industry, CA (US)

(21) Appl. No.: 19/531,281

(22) Filed: Feb. 5, 2026

(30) Foreign Application Priority Data
Mar. 4, 2025 (TW) 114107895

(51) Int. Cl. G06F 1/20; H05K 7/20

(52) U.S. Cl. CPC G06F 1/20; H05K 7/2039

(57) ABSTRACT

A computer chassis with heat dissipation and transparency includes a chassis body including a transparent front panel, transparent side panels and a transparent top cover, and a ventilation module including an air intake panel mounted on a light-transmitting plate, a heat dissipation device assembled at a bottom of a support plate and having an air outlet provided with heat dissipation fins corresponding to each air inlet on the support plate and preset fans mounted at a bottom of the heat dissipation device. A supporting surface of the support plate provides stable support for the light-transmitting plate and the air intake panel. The air intake panel is assembled on an air intake panel mounting portion formed by hollowing out the light-transmitting plate of the transparent top cover, thereby maintaining the ventilation effect inside the chassis body while ensuring better light transmission.

This application claims the priority benefit of Taiwan patent application number 114107895, filed on Mar. 4, 2025.

### BACKGROUND OF THE INVENTION

### 1. Field of the Invention

The present invention relates to a computer chassis with heat dissipation and transparency, particularly a chassis body with a light-transmitting plate of a transparent top cover, preferably made of glass material with good light transmission, and an air intake panel is installed on an air intake panel mounting portion formed by cutting out a hole in the glass, thereby maintaining the ventilation effect inside the chassis body while ensuring better light transmission.

### 2. Description of the Related Art

Nowadays, in order to gain a better share of the computer host consumer market and attract consumers' attention, computer hosts with distinctive appearances and visual effects have become one of the research targets for various manufacturers. For example, a unified color scheme or a cool LED visual effect, along with a computer chassis designed with glass materials to enhance the light transmission inside the computer chassis. However, the thick glass material is not conducive to heat dissipation inside the chassis, which is a key area that those in this industry urgently need to research and improve.

### SUMMARY OF THE INVENTION

The main object of this invention is to provide a computer chassis with heat dissipation and transparency, comprising a chassis body and a ventilation module. The chassis body comprises a transparent front panel, at least one transparent side panel and a transparent top cover. The transparent front panel has a first light-transmitting surface on a surface thereof, the at least one transparent side panel has a second light-transmitting surface on a surface thereof, and the transparent top cover has a support plate, and a surface of the support plate has at least one air inlet. A light-transmitting plate with a third light-transmitting surface is then assembled on a supporting surface at a top of the support plate, and an air intake panel mounting portion is provided on the light-transmitting plate. The ventilation module comprises an air intake panel mounted on the air intake panel mounting portion of the light-transmitting plate. A heat dissipation device is then assembled at a bottom of the support plate of the chassis body, and an air outlet of the heat dissipation device is provided with a plurality of heat dissipation fins corresponding to each air inlet. At least one preset fan is then assembled at a bottom of the heat dissipation device. The supporting surface of the support plate provides stable support for the light-transmitting plate and the air intake panel. The air intake panel is assembled on the air intake panel mounting portion formed by hollowing out the light-transmitting plate of the transparent top cover, thereby maintaining the ventilation effect inside the chassis body while ensuring better light transmission.

Another object of the present invention is that a switch mounting structure is formed between the transparent front panel, the at least one transparent side panel and the transparent top cover of the chassis body, and is tilted at an angle in combination with the three-party positions. The switch mounting structure has a first intersection between the transparent front panel and the at least one transparent side panel, a second intersection between the transparent front panel and the transparent top cover, and a third intersection between the at least one transparent side panel and the transparent top cover. A triangular-shaped floating switch is further assembled on the switch mounting structure. The floating switch comprises a switch holder base assembled on the switch mounting structure, and an assembly space is formed in the switch holder base for assembling a circuit board. The circuit board has a push-button switch on its surface, and a fixing shell is assembled on an outside of the circuit board, and comprises a pressing surface formed on a surface thereof and abutting against the push-button switch.

Still another object of the present invention is that the switch mounting structure has a beveled first switch mounting portion disposed on the transparent front panel adjacent to the at least one transparent side panel, and a beveled second switch mounting portion disposed on the support plate adjacent to the transparent front panel and the at least one transparent side panel. Furthermore, an extension plate extends from one side of the second switch mounting portion.

Still another object of the present invention is that a bottom of the chassis body is further assembled with a heat dissipation base, and surfaces of a plurality of heat dissipation plates formed around the heat dissipation base are provided with a plurality of first heat dissipation holes. A heat dissipation buffer space is then formed on the heat dissipation base, and two heat dissipation cover plates with a plurality of second heat dissipation holes are provided above and below the heat dissipation base. Furthermore, the heat dissipation base has a plurality of support brackets at various points around its bottom periphery.

### BRIEF DESCRIPTION OF THE DRAWINGS

FIG. 1 is a three-dimensional external view of the computer chassis with heat dissipation and transparency of the present invention.

FIG. 2 is a three-dimensional exploded view of the computer chassis with heat dissipation and transparency of the present invention.

FIG. 3 is a schematic assembly diagram of the floating switch of the present invention.

FIG. 4 is a three-dimensional exploded view of the heat dissipation base of the present invention.

FIG. 5 is a three-dimensional exploded view of the ventilation module of the present invention.

FIG. 6 is a three-dimensional exploded view of the ventilation module of the present invention from another viewing angle.

FIG. 7 is a three-dimensional exploded view of the floating switch of the present invention.

FIG. 8 is a three-dimensional exploded view of the floating switch of the present invention from another viewing angle.

### DETAILED DESCRIPTION OF THE PREFERRED EMBODIMENT

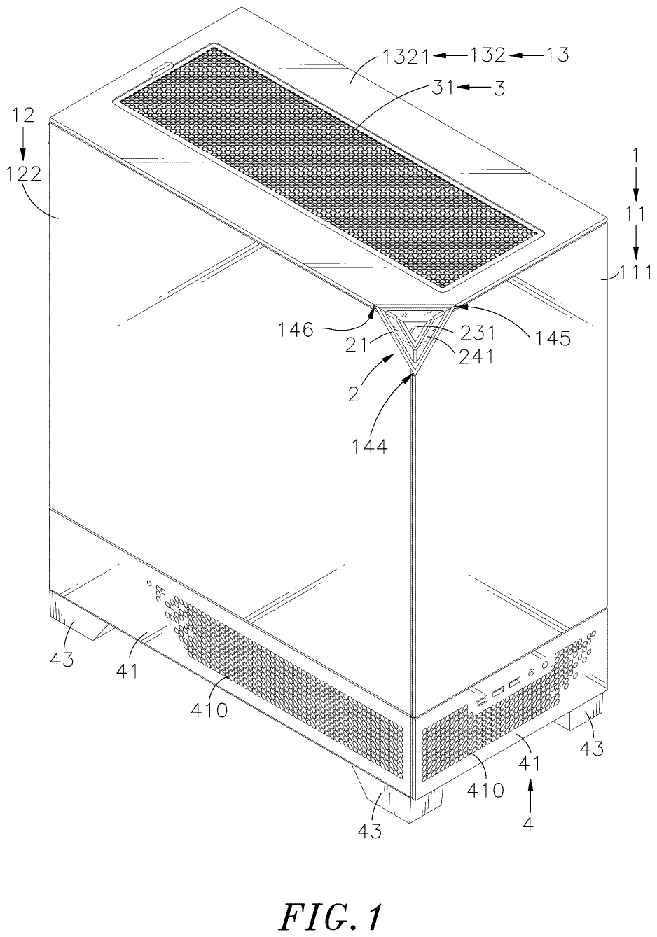

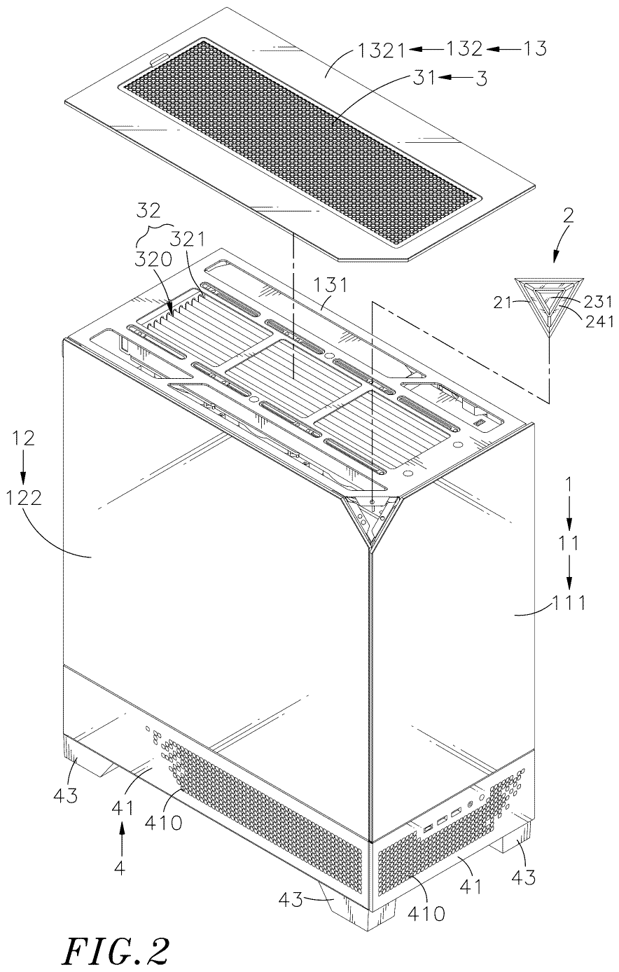

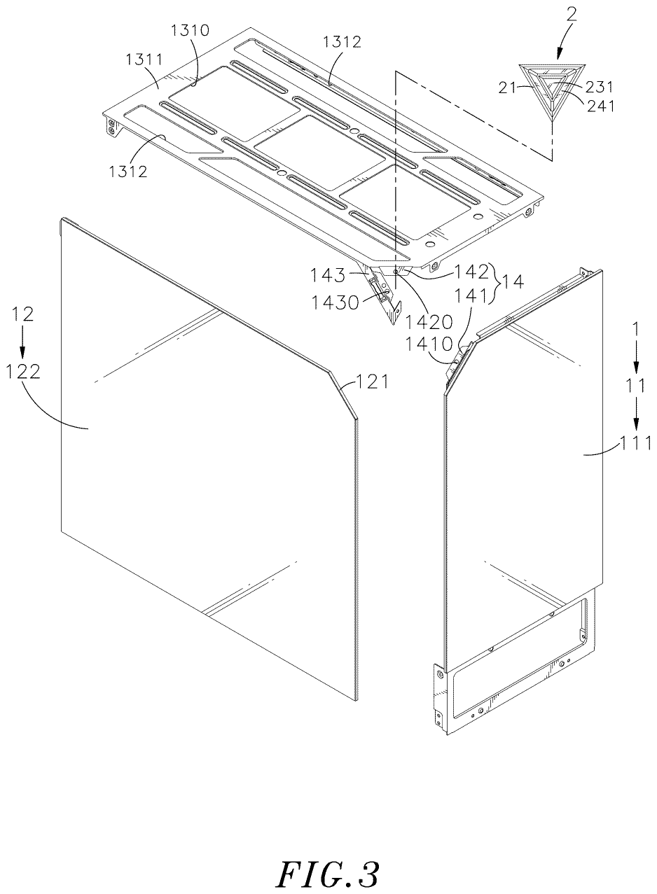

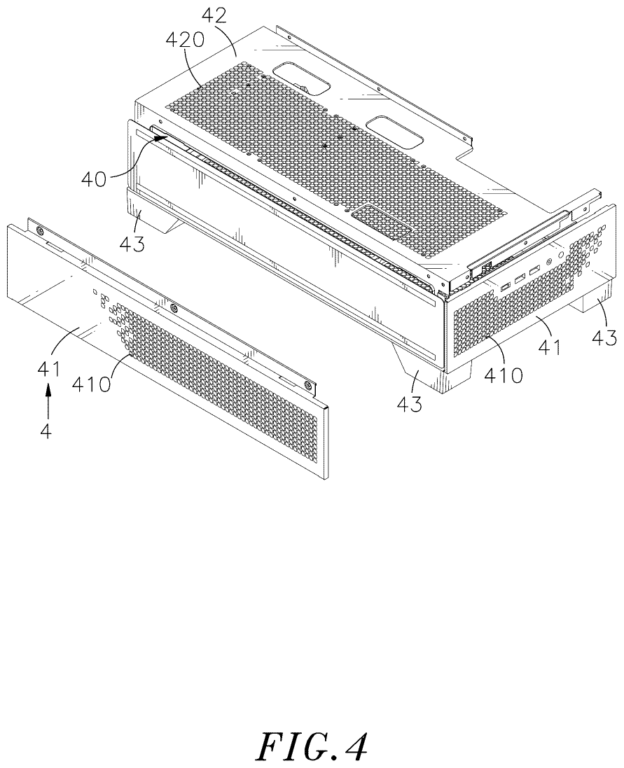

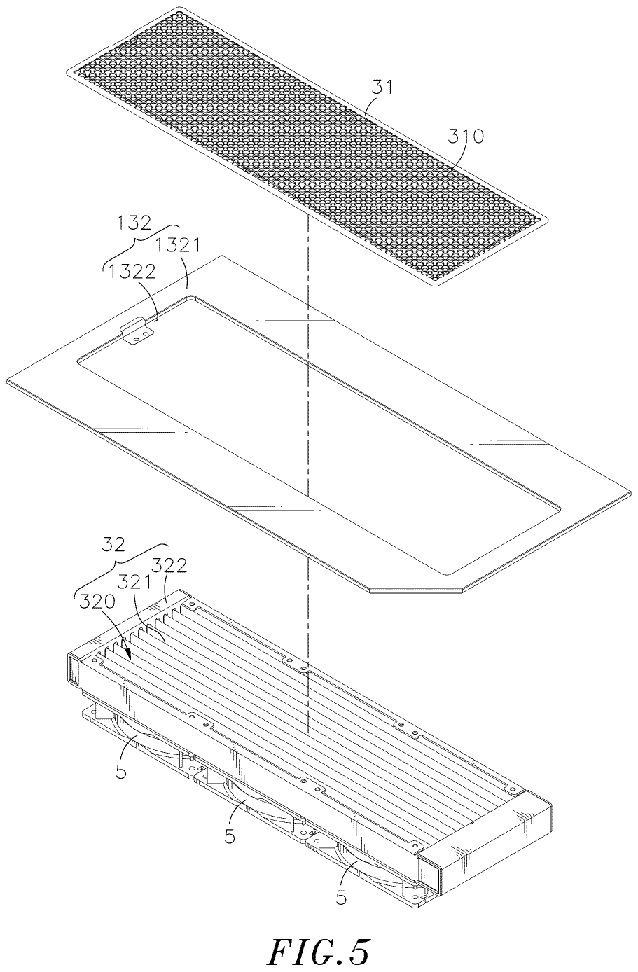

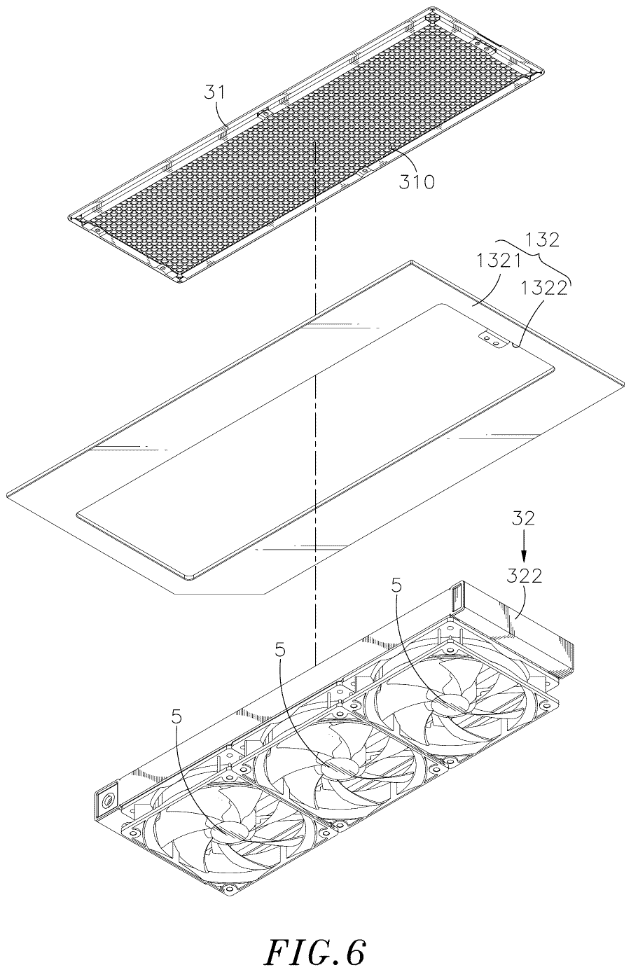

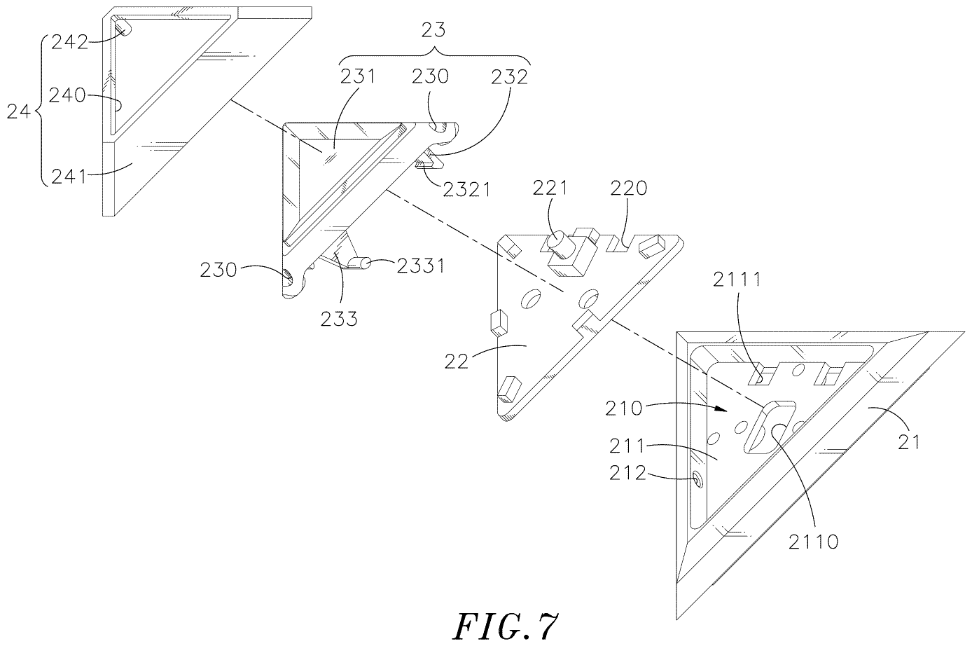

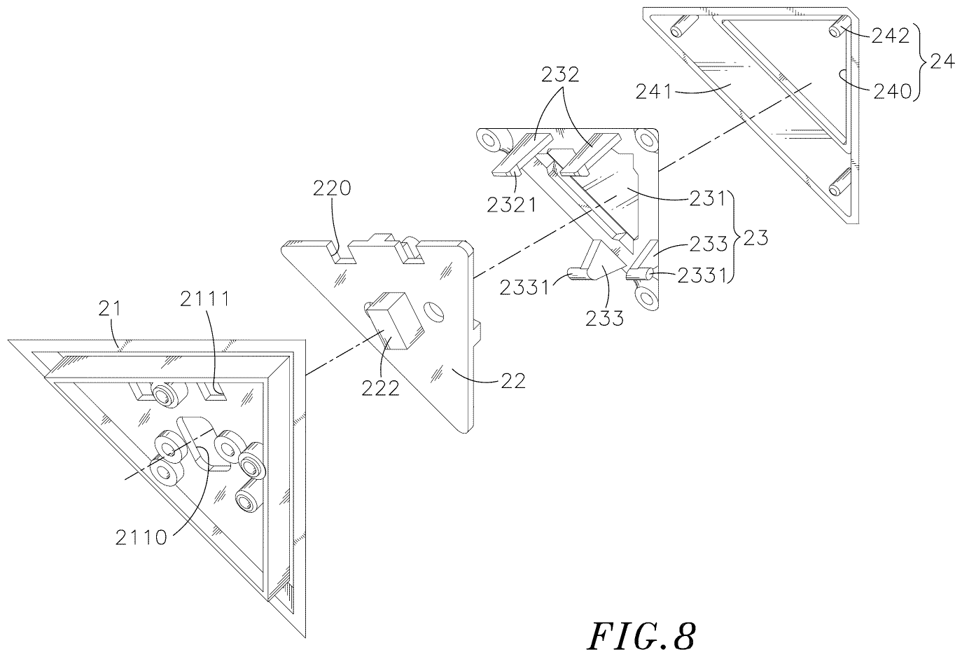

Please refer to FIGS. 1 to 8. The computer chassis with heat dissipation and transparency of this invention mainly comprises a chassis body 1, a floating switch 2 and a ventilation module 3. The connection relationship of the aforementioned components is as follows:

The chassis body 1 comprises a transparent front panel 11, at least one transparent side panel 12 and a transparent top cover 13. The transparent front panel 11 has a first light-transmitting surface 111 formed on a surface thereof. The at least one transparent side panel 12 has one top corner thereof beveled to form a limiting cut surface 121 adjacent to the transparent front panel 11, and the at least one transparent side panel 12 further has a second light-transmitting surface 122 formed on a surface thereof. The transparent top cover 13 comprises a support plate 131, and a light-transmitting plate 132 with a third light-transmitting surface 1321 is assembled at a supporting surface 1311 of a top of the support plate 131, and the light-transmitting plate 132 is provided with an air intake panel mounting portion 1322. The support plate 131 has a surface thereof provided with at least one air inlet 1310 and a plurality of buffer openings 1312 located around each air inlet 1310. A switch mounting structure 14 is formed between the transparent front panel 11, the at least one transparent side panel 12 and the transparent top cover 13 and is tilted at an angle in combination with the three-party positions. The switch mounting structure 14 comprises a first switch mounting portion 141 that is beveled and disposed on the transparent front panel 11 adjacent to the at least one transparent side panel 12, a second switch mounting portion 142 that is beveled and disposed on the support plate 131 adjacent to the transparent front panel 11 and the at least one transparent side panel 12, and an extension plate 143 with a plurality of locking holes 1430 extending from one side of the second switch mounting portion 142.

The first switch mounting portion 141 is provided with at least one first assembly hole 1410, and the second switch mounting portion 142 is provided with at least one second assembly hole 1420.

The floating switch 2 comprises a switch holder base 21 assembled on the switch mounting structure 14, a circuit board 22 mounted in the switch holder base 21, a fixing shell 23 mounted on an outside of the circuit board 22, and a top cover 24 covering a periphery of the fixing shell 23. The switch holder base 21 comprises a bottom plate 211, a positioning groove 2110 and at least one first fixing hole 2111 located on the bottom plate 211, an assembly space 210 formed therein for assembling the circuit board 22, and two positioning holes 212 provided on inner wall surfaces of two opposite sides thereof. The circuit board 22 comprises a push-button switch 221 mounted on a surface thereof, at least one second fixing hole 220 recessed on at least one side thereof corresponding to the at least one first fixing hole 2111, and a positioning block 222 protruded from a bottom surface thereof and passing through the positioning groove 2110 of the switch holder base 21. The fixing shell 23 comprises a pressing surface 231 formed on a surface thereof and abutted against the push-button switch 221, at least one long first positioning arm 232 extending downward from a bottom thereof and inserted through the at least one second fixing hole 220 and the at least one first fixing hole 2111, a stop block 2321 protruded from a bottom of each of the at least one first positioning arm 232, two second positioning arms 233 respectively extending downward from two sides thereof and far from the at least one first positioning arm 232, and a positioning rod 2331 extending outward from each of the two second positioning arms 233 and fixed within one respective positioning hole 212 of the switch holder base 21, and a plurality of third fixing holes 230 provided around the periphery thereof for mounting the top cover 24. The top cover 24 comprises an opening 240 that exposes the pressing surface 231 of the fixing shell 23, a plurality of three-dimensional surfaces 241 gradually extending upward at a periphery thereof, and a plurality of fixing rods 242 that extend downward and are mounted into the plurality of third fixing holes 230 of the fixing shell 23.

The ventilation module 3 comprises an air intake panel 31 provided with a plurality of ventilation holes 310 and disposed on the air intake panel mounting portion 1322 of the light-transmitting plate 132, and a heat dissipation device 32 assembled at a bottom of the support plate 131 of the chassis body 1. The heat dissipation device 32 comprises an air outlet 320, a plurality of heat dissipation fins 321 mounted in the air outlet 320 corresponding to each air inlet 1310, heat-conducting parts 322 located on two opposite sides thereof and connected to the plurality of heat dissipation fins 321 for heat transfer, and at least one preset fan 5 assembled at a bottom thereof.

Furthermore, a heat dissipation base 4 is further assembled at a bottom of the chassis body 1. The heat dissipation base 4 comprises a plurality of heat dissipation plates 41 arranged around a periphery thereof, a plurality of first heat dissipation holes 410 located on surfaces of the plurality of heat dissipation plates 41, a heat dissipation buffer space 40 formed therein, two heat dissipation cover plates 42 respectively located at both top and bottom sides thereof, a plurality of second heat dissipation holes 420 located on surfaces of the two heat dissipation cover plates 42, and a plurality of support brackets 43 provided at various points around a bottom periphery thereof.

The switch mounting structure 14 further comprises a first intersection 144 between the transparent front panel 11 and the at least one transparent side panel 12, a second intersection 145 between the transparent front panel 11 and the transparent top cover 13 and a third intersection 146 between the at least one transparent side panel 12 and the transparent top cover 13 at the intersection of the three-party positions of the transparent front panel 11, the at least one transparent side panel 12 and the transparent top cover 13, so that the three points of the first intersection 144, the second intersection 145 and the third intersection 146 are intersected to form the triangle of the switch mounting structure 14.

Furthermore, the floating switch 2 is arranged in a triangular shape to match the three-point intersection of the switch mounting structure 14, and is tilted at an angle on one side of the chassis body 1 for the convenience of users pressing the power button. Its tilt angle is designed to accommodate the placement of the host. When the host is placed under the desk, it is easy to press and apply force; when the host is placed on the desk, it also works with the tilted push-button switch 221. Compared to traditional push-button switches located on the top or front panel, the floating switch 2 is easier to press, saving the users' effort and improving convenience. The power switch on a computer host is a component that the users press at least once a day, and its location must be convenient for the users during long-term operation. If the pressing position is inconvenient, the users may not feel anything at first, but over time it will cause fatigue for the users. Simply changing the position of the switch can greatly reduce user fatigue, which is the effect of the tilt angle and position design of the floating switch 2 in this invention.

When assembling the computer chassis with heat dissipation and transparency of the present invention, the switch mounting structure 14 is formed between the transparent front panel 11, the at least one transparent side panel 12 and the transparent top cover 13 of the chassis body 1, and is tilted at an angle in combination with the three-party positions. The floating switch 2 is then assembled onto the switch mounting structure 14, and secured to the switch holder base 21 of the floating switch 2 by means of a plurality of preset fasteners (not shown in the figures) passing through the at least one first assembly hole 1410, the at least one second assembly hole 1420 and the plurality of locking holes 1430 of the switch mounting structure 14. The circuit board 22 is further assembled inside the assembly space 210 of the switch holder base 21, and the positioning block 222 protruding from the bottom surface of the circuit board 22 forms a positioning point at the positioning groove 2110 of the bottom plate 211 of the switch holder base 21. The fixing shell 23 is then assembled onto the circuit board 22, and a bottom of the pressing surface 231 of the fixing shell 23 abuts against a surface of the push-button switch 221 on the circuit board 22. Meanwhile, the at least one long first positioning arm 232 extending downward from the fixing shell 23 is inserted through each of the at least one second fixing hole 220 and exits through each of the at least one first fixing hole 2111, so that the stop block 2321 located at an end of the at least one first positioning arm 232 exits the switch holder base 21, and the two second positioning arms 233, which are shorter and located away from a side of each of the at least one first positioning arm 232, are passed through the circuit board 22, and the positioning rods 2331 extending from the two second positioning arms 233 are then assembled into the two positioning holes 212 of the switch holder base 21 to form a positioning. The top cover 24 is then positioned on each of the plurality of third fixing holes 230 of the fixing shell 23 through the plurality of fixing rods 242, so that the pressing surface 231 of the fixing shell 23 is exposed at the opening 240 of the top cover 24, thereby completing the assembly of the floating switch 2 of the present invention.

Furthermore, the air intake panel 31 of the aforementioned ventilation module 3 is mounted on the air intake panel mounting portion 1322 of the light-transmitting plate 132 of the chassis body 1, and a bottom side of the light-transmitting plate 132 relies on the support plate 131 to distribute gravity. The heat dissipation device 32 is assembled at the bottom of the support plate 131, the heat dissipation device 32 is provided with the air outlet 320 corresponding to each air inlet 1310, and the at least one preset fan 5 is assembled at the bottom of the heat dissipation device 32.

In addition, the heat dissipation base 4 at the bottom of the chassis body 1 is assembled from the plurality of heat dissipation plates 41 to form the heat dissipation buffer space 40 inside, and the plurality of support brackets 43 are provided at various points around a bottom periphery of the heat dissipation base 4 to provide support.

The aforementioned transparent front panel 11, at least one transparent side panel 12 and transparent top cover 13 are made of glass and are beveled at an angle in combination with the three-party positions on the chassis body 1 in conjunction with the floating switch 2. By utilizing the light-transmitting properties of glass, a floating effect is created where the switch appears to be suspended in mid-air, providing the host with a pleasing visual experience and thus stimulating consumer desire. The covering of the top cover 24 of the floating switch 2 with the plurality of three-dimensional surfaces 241 enhances the sense of depth of the floating switch 2 and gives it a more floating effect. The transparent front panel 11, the at least one transparent side panel 12 and the transparent top cover 13 can also be made of transparent acrylic sheet or other transparent materials, which are materials that can create a switch floating visual effect. Such simple and uniform variations and modifications do not limit the scope of protection of this invention, and are therefore clearly stated.

Furthermore, the top cover 24 of the aforementioned floating switch 2 can also be made of transparent materials such as glass, acrylic sheet, or other transparent materials. LEDs or other light-emitting elements can be installed on the switch holder base 21 or the circuit board 22 of the floating switch 2 to enhance the light-emitting effect inside the floating switch 2 and further enhance the floating sensation on the chassis body 1.

Furthermore, when the aforementioned floating switch 2 is pressed, the at least one long first positioning arm 232 on the fixing shell 23 extends downward as it is pressed, thus providing a long-stroke pressing feel. This pressure is released after the pressing surface 231 presses against the push-button switch 221 at the bottom. At this point, the two shorter second positioning arms 233 on the fixing shell 23 are positioned by the positioning rod 2331 and will not move excessively. As the pressure is released, the at least one first positioning arm 232 can spring back upward to its original position. The stop block 2321 at the bottom of the at least one first positioning arm 232 will block the bottom plate 211 of the switch holder base 21 when the at least one first positioning arm 232 bounces back upward, so as to prevent the at least one first positioning arm 232 from detaching from the switch holder base 21.

Furthermore, the light-transmitting plate 132 of the transparent top cover 13 is preferably made of glass material with good light transmission. Therefore, the present invention assembles the air intake panel 31 onto the air intake panel mounting portion 1322, which is formed by cutting out a hole in the glass, to maintain ventilation inside the chassis body 1 in an environment with good light transmission. To prevent the weight of the glass from affecting the overall support of the chassis body 1, the bottom side of the light-transmitting plate 132 is provided with the support plate 131 for support. The heat dissipation device 32 assembled at the bottom of the support plate 131 provides air cooling through the at least one preset fan 5 at the bottom. This heat source inside the chassis body 1 is conducted to each of the plurality of heat dissipation fins 321 through the heat-conducting parts 322 of the heat dissipation device 32. Then, the air blown out by the at least one preset fan 5 passes through the plurality of ventilation holes 310 on the air intake panel 31 and is discharged outside the chassis body 1. The plurality of buffer openings 1312 on the support plate 131 guide any air that cannot be blown out back into the chassis body 1 for re-air cooling.

As described above, the bottom of the chassis body 1 is further assembled with the heat dissipation base 4. Preferably, the chassis body 1 is assembled by using the transparent front panel 11, the at least one transparent side panel 12 and the transparent top cover 13 made of glass to create an optimal floating visual effect for the switch. However, even with the ventilation module 3, the heat dissipation effect may not be sufficient due to the glass assembly on at least three sides. Therefore, the heat dissipation base 4 can conduct heat from inside the chassis body 1 to the heat dissipation buffer space 40 to prevent heat from accumulating inside the chassis body 1. The plurality of heat dissipation plates 41 and the two heat dissipation cover plates 42 surrounding the heat dissipation base 4 are for discharging the heat energy stored inside the heat dissipation base 4.

Furthermore, the present invention primarily addresses the use of glass material with good light transmission for the light-transmitting plate 132 of the transparent top cover 13, and the assembly of the air intake panel 31 onto the air intake panel mounting portion 1322 formed by cutting out a hole in the glass, thereby maintaining the ventilation effect inside the chassis body 1 while ensuring good light transmission. The secondary purpose is to install the floating switch 2, which is beveled at an angle in combination with the three-party positions on the chassis body 1, namely the transparent front panel 11, the at least one transparent side panel 12 and the transparent top cover 13, thereby creating an optimal floating visual effect.

What the invention claimed is:

1. A computer chassis with heat dissipation and transparency, comprising:
a chassis body comprising a transparent front panel, at least one transparent side panel and a transparent top cover, said transparent front panel comprising a first light-transmitting surface formed on a surface thereof, said at least one transparent side panel comprising a second light-transmitting surface formed on a surface thereof, said transparent top cover comprising a support plate and a light-transmitting plate, said support plate comprising a supporting surface on a top thereof and at least one air inlet on said supporting surface, said light-transmitting plate being assembled on said supporting surface of said support plate, said light-transmitting plate comprising a third light-transmitting surface and an air intake panel mounting portion;
a heat dissipation base assembled at a bottom of said chassis body, said heat dissipation base comprising a plurality of heat dissipation plates arranged around a periphery thereof, a plurality of first heat dissipation holes located on surfaces of said plurality of heat dissipation plates, a heat dissipation buffer space formed therein, two heat dissipation cover plates respectively located at both top and bottom sides thereof and a plurality of second heat dissipation holes located on surfaces of said two heat dissipation cover plates; and
a ventilation module comprising an air intake panel disposed on said air intake panel mounting portion of said light-transmitting plate, a heat dissipation device assembled at a bottom of said support plate of said chassis body, said heat dissipation device comprising an air outlet, a plurality of heat dissipation fins mounted in said air outlet corresponding to each of said at least one air inlet and at least one preset fan assembled at a bottom thereof; and
wherein said supporting surface of said support plate provides stable support for said light-transmitting plate and said air intake panel, while said heat dissipation base dissipates heat from an inside of said chassis body.

2. The computer chassis with heat dissipation and transparency as claimed in claim 1, wherein said supporting surface of said support plate is transparent, and said support plate further comprises a plurality of buffer openings provided around said at least one air inlet.

3. The computer chassis with heat dissipation and transparency as claimed in claim 1, wherein said heat dissipation device of said ventilation module further comprises two heat-conducting parts respectively located at two opposite sides thereof and connected to said plurality of heat dissipation fins for heat transfer.

4. The computer chassis with heat dissipation and transparency as claimed in claim 1, wherein said air intake panel of said ventilation module comprises a plurality of ventilation holes.

5. The computer chassis with heat dissipation and transparency as claimed in claim 1, wherein said chassis body further comprises a switch mounting structure formed between said transparent front panel, said at least one transparent side panel and said transparent top cover and is tilted at an angle in combination with the three-party positions of said transparent front panel, said at least one transparent side panel and said transparent top cover, said switch mounting structure comprising a first intersection between said transparent front panel and said at least one transparent side panel, a second intersection between said transparent front panel and said transparent top cover and a third intersection between said at least one transparent side panel and said transparent top cover; the computer chassis with heat dissipation and transparency further comprises a triangular-shaped floating switch assembled on said switch mounting structure, said floating switch comprising a switch holder base assembled on said switch mounting structure, an assembly space formed in said switch holder base, a circuit board mounted in said assembly space inside said switch holder base and a fixing shell mounted on an outside of said circuit board, said circuit board comprising a push-button switch mounted on a surface thereof, said fixing shell comprising a pressing surface formed on a surface thereof and abutted against said push-button switch.

6. The computer chassis with heat dissipation and transparency as claimed in claim 5, wherein said switch mounting structure further comprises a first switch mounting portion that is beveled and disposed on said transparent front panel adjacent to said at least one transparent side panel, a second switch mounting portion that is beveled and disposed on said support plate adjacent to said transparent front panel and said at least one transparent side panel, and an extension plate extending from one side of said second switch mounting portion.

7. The computer chassis with heat dissipation and transparency as claimed in claim 1, wherein said heat dissipation base comprises a plurality of support brackets at different points around a bottom periphery thereof.

8. A computer chassis with heat dissipation and transparency, comprising:
a chassis body comprising a transparent front panel, at least one transparent side panel, a transparent top cover and a switch mounting structure, said transparent front panel comprising a first light-transmitting surface formed on a surface thereof, said at least one transparent side panel comprising a second light-transmitting surface formed on a surface thereof, said transparent top cover comprising a support plate and a light-transmitting plate, said support plate comprising a supporting surface on a top thereof and at least one air inlet on said supporting surface, said light-transmitting plate being assembled on said supporting surface of said support plate, said light-transmitting plate comprising a third light-transmitting surface and an air intake panel mounting portion; said switch mounting structure being formed between said transparent front panel, said at least one transparent side panel and said transparent top cover and tilted at an angle in combination with the three-party positions of said transparent front panel, said at least one transparent side panel and said transparent top cover, said switch mounting structure comprising a first intersection between said transparent front panel and said at least one transparent side panel, a second intersection between said transparent front panel and said transparent top cover and a third intersection between said at least one transparent side panel and said transparent top cover;
a triangular-shaped floating switch assembled on said switch mounting structure, said floating switch comprising a switch holder base assembled on said switch mounting structure, an assembly space formed in said switch holder base, a circuit board mounted in said assembly space inside said switch holder base and a fixing shell mounted on an outside of said circuit board, said circuit board comprising a push-button switch mounted on a surface thereof, said fixing shell comprising a pressing surface formed on a surface thereof and abutted against said push-button switch; and
a ventilation module comprising an air intake panel disposed on said air intake panel mounting portion of said light-transmitting plate and a heat dissipation device assembled at a bottom of said support plate of said chassis body, said heat dissipation device comprising an air outlet, a plurality of heat dissipation fins mounted in said air outlet corresponding to each of said at least one air inlet and at least one preset fan assembled at a bottom thereof; and
wherein said supporting surface of said support plate provides stable support for said light-transmitting plate and said air intake panel.
